(19) United States
(12) Patent Application Publication
(10) Pub. No.: US 2026/0239949 A1
(43) Pub. Date: Aug. 13, 2026

(54) MDIP SEMICONDUCTOR DEVICE INCLUDING BACKFILLED VIAS

(71) Applicant: Sandisk Technologies, Inc., Milpitas, CA (US)

(72) Inventors: Jayavel Pachamuthu, San Jose, CA (US); Rama Shukla, Saratoga, CA (US)

(73) Assignee: Sandisk Technologies, Inc., Milpitas, CA (US)

(21) Appl. No.: 19/052,757

(22) Filed: Feb. 13, 2025

(51) Int. Cl. H01L 23/00; H01L 23/48; H01L 25/07; H10B 80/00

(52) U.S. Cl. CPC H10W 20/20; H10W 90/00; H10B 80/00; H10W 72/934; H10W 72/942; H10W 72/944; H10W 80/312; H10W 80/327; H10W 80/743; H10W 90/26; H10W 90/297; H10W 90/792

(57) ABSTRACT

A mirrored die pair (mDiP) semiconductor device includes deep trench vias having portions at the upper and/or lower surfaces of the mDiP device that are backfilled with conductive material. Backfilling the deep trench vias ensures electrically coupled, solid, low resistive bonding, for example between a stack of mDiP semiconductor devices.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. The non-volatile memory products portability, versatility and customized design, along with their high reliability and ultra-high capacity, have made such memory devices ideal for use in a wide variety of electronic devices, including for example digital cameras, digital music players, video game consoles, PDAs, cellular telephones and solid state drives (SSDs).

Artificial intelligence (AI) and machine learning (ML) applications demand advanced memory and computing solutions with high performance, low power dissipation, low latency, and high bandwidth to support intensive read and write operations during the features training and inference phases. To meet these requirements, 3D BiCS (Bit Cost Scalable) technology has emerged as a viable solution, offering rapid scaling to achieve higher storage capacity per die.

Traditionally, multi-die stacking of, for example, BiCS memory dies using wire bonding has been employed to increase storage capacity. However, this approach suffers from significant drawbacks, including limitations in semiconductor die thicknesses. In particular, given the ever-present drive to provide greater storage capacity in a smaller form factor, semiconductor devices are made as thin as possible, currently about 36 microns (μm) or smaller. However, mechanical or thermal stress factors causes die warping, chipping and/or cracking during semiconductor package fabrication are proving a barrier to further reduction in thickness of semiconductor dies.

Additionally, conventional multi-die stacking methods face significant limitations in meeting customer requirements for compute-in-memory capability in artificial intelligence/machine learning (AI/ML) applications. One major drawback is the large pin capacitance (pin-cap), which increases power consumption and degrades signal integrity, thereby reducing overall performance. Furthermore, traditional stacking approaches offer limited parallelism, restricting the number of simultaneous read and write operations, which is critical for high-speed AI/ML workloads. Higher read latency is another concern, as data access times are prolonged due to increased interconnect distances and signal propagation delays between stacked dies. Reliability issues associated with micro-bumps further exacerbate these challenges, as micro-bump-induced stress, electromigration, and thermal cycling can lead to degraded performance and potential failure over time. These limitations collectively hinder the adoption of conventional multi-die stacking for AI/ML compute-in-memory architectures, necessitating innovative design approaches to overcome these constraints..

To address these challenges, a mirrored die pair (mDiP) bonding method has been developed, where two memory wafers are bonded face-to-face. The face-to-face bonding significant reduces warping, and allows the wafers to be further thinned without chipping and/or cracking during semiconductor package processing or assembly. Moreover, the die pairs effectively double the storage capacity, enables parallelism, bandwidth increase for compute applications. Electrical connections in mDiP die stacks are accomplished using TSVs (through silicon vias) or other high aspect ratio deep trench vias which efficiently route high-voltage, logic, I/O, and other signals from a controller die to the memory dies.

This approach introduces new challenges, for example in the formation of the vias. Conventional formation of TSVs results in vias which are under-filled, with a concave meniscus being formed at the top and/or bottom of each TSV. Under-filled TSVs can result in high resistive and voids. In other words, under-filled TSVs are electrically uncoupled. These defects lead to significant signal transmission losses, data corruption, compute inference latency and reliability concerns that could hinder product performance and adoptability or usage in the field.

### DESCRIPTION OF THE DRAWINGS

FIG. 1 is a flowchart for forming an mDiP memory device according to embodiments of the present technology.

FIG. 2 is a top view of a first semiconductor wafer, and a first semiconductor die therefrom, according to embodiments of the present technology.

FIG. 3 is a top view of a second semiconductor wafer, and a second semiconductor die therefrom, according to embodiments of the present technology.

FIG. 4 is a cross-sectional edge view of a first semiconductor of the first wafer die according to embodiments of the present technology.

FIG. 5 is a cross-sectional edge view of a second semiconductor die of the second wafer according to embodiments of the present technology.

FIG. 6 is a cross-sectional edge view of the first and second wafers being joined to form a CBA memory wafer according to embodiments of the present technology.

FIG. 7 is a cross-sectional edge view of first and second CBA memory wafers positioned for being joined together according to embodiments of the present technology.

FIG. 8 is a cross-sectional edge view of first and second CBA memory wafers joined together to form an mDiP memory wafer according to embodiments of the present technology.

FIG. 9 is a flowchart for forming an mDiP semiconductor memory device from stacked mDiP memory wafers according to embodiments of the present technology.

FIG. 10 is a cross-sectional edge view of an mDiP memory wafer with a first surface thinned in backgrind and polishing processes according to embodiments of the present technology.

FIG. 11 is an enlarged cross-sectional view of a first surface of the mDiP memory wafer showing concave menisci formed in the deep trench vias after thinning of the first wafer surface according to embodiments of the present technology.

FIG. 12 is an enlarged cross-sectional view of the first surface of the mDiP memory wafer showing processing of the deep trench vias to enlarge the vias at the first surface according to embodiments of the present technology.

FIG. 13 is an enlarged cross-sectional view of the first surface of the mDiP memory wafer showing deep trench vias having enlarged filled sections at the first surface according to embodiments of the present technology.

FIG. 14 is a cross-sectional edge view of an mDiP memory wafer with a second surface thinned in backgrind and polishing processes according to embodiments of the present technology.

FIG. 15 is a cross-sectional edge view of a pair of mDiP memory wafer bonded together at the enlarged filled surface sections according to embodiments of the present technology.

FIG. 16 is an enlarged cross-sectional edge view of the bonded enlarged filled surface sections of the deep trench vias from first and second bonded mDiP memory wafers according to embodiments of the present technology.

FIG. 17 is an enlarged cross-sectional edge view of the bonded surface sections of the deep trench vias from first and second bonded mDiP memory wafers according to an alternative embodiment of the present technology.

FIG. 18 is an enlarged cross-sectional edge view of the bonded surface sections of the deep trench vias from first and second bonded mDiP memory wafers according to a further alternative embodiment of the present technology.

FIG. 19 is a cross-sectional edge view of a plurality of mDiPs stacked on a substrate according to embodiments of the present technology.

### DETAILED DESCRIPTION

The present technology will now be described with reference to the figures, which in embodiments, relate to a mirrored die pair (mDiP) semiconductor device including deep trench vias including portions at the upper and/or lower surfaces of the mDiP device that are backfilled with conductive material. As noted in the Background section, processing of mDiP semiconductor wafers results in vias which have a concave meniscus at the first and/or second surfaces of the mDiP wafers. By backfilling these concave menisci, this ensures electrically coupled, solid, and low resistive bonding, for example with another mDiP semiconductor device or wafer.

In one example, the backfilled portions of the deep trench vias from two bonded mDiP wafers may first be enlarged and then backfilled. This ensures a large surface area at the bonding side of bonding pads or micro bumps. In a further example, where first and second vias in adjacent mDiP wafers are bonded together, the surface portion of the first via may be enlarged and backfilled, where the surface portion of the second via may be smaller and backfilled. This increases the likelihood that the second via will be completely within the bonding surface or footprint of the second via, thus minimizing resistivity of the bonding pad or micro-bump. A further example may be similar to the above example, but the surface portions of both vias that are bonded together are made smaller and backfilled.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology in as much as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

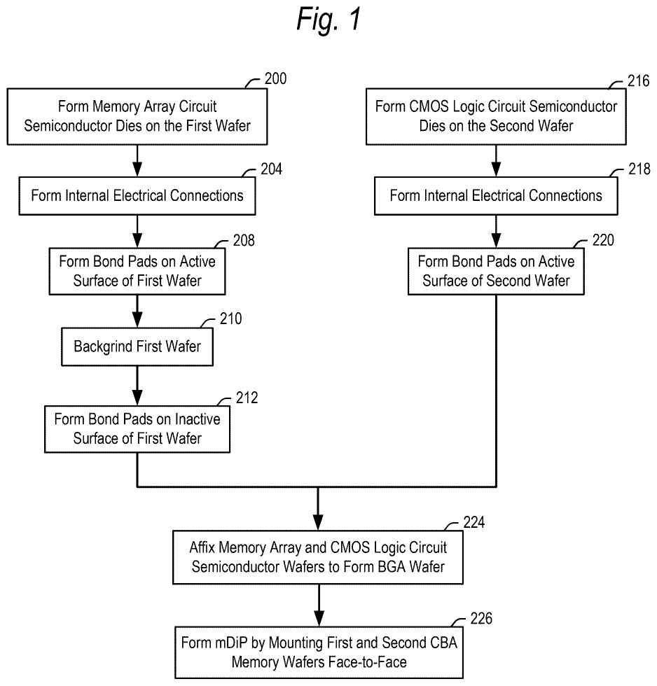

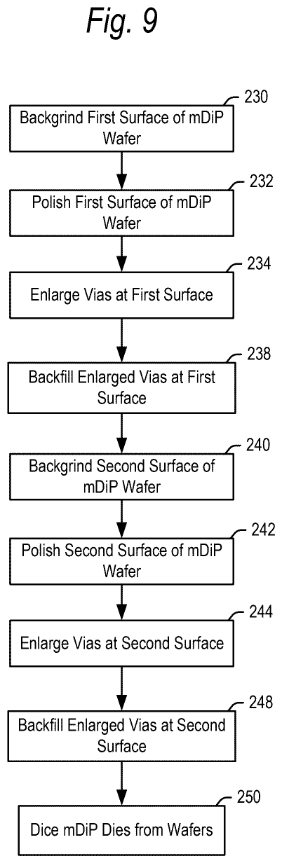

An embodiment of the present technology will now be explained with reference to the flowchart of FIGS. 1 and 9, and the views of FIGS. 2-8 and 10-19. In step 200, a first semiconductor wafer 100 may be processed into a number of first semiconductor dies 102, such as for example memory array semiconductor dies, as shown in FIG. 2. The first semiconductor wafer 100 may start as an ingot of wafer material which may be monocrystalline silicon grown according to either a Czochralski (CZ) or floating zone (FZ) process. However, first wafer 100 may be formed of other materials and by other processes in further embodiments.

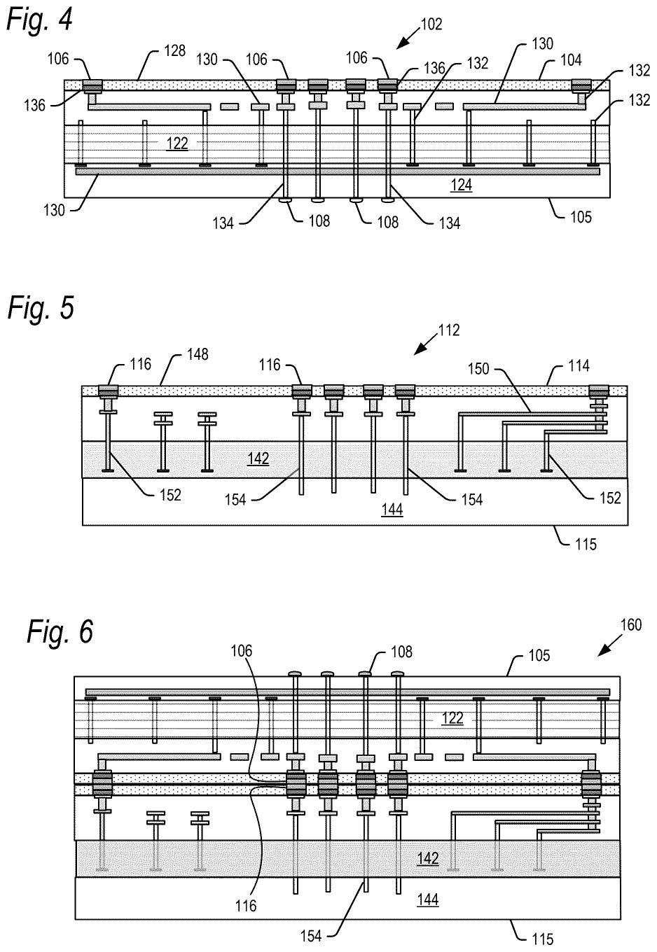

The semiconductor wafer 100 may be cut from the ingot and polished on both the first major planar surface 104, and second major planar surface 105 (FIG. 4) opposite surface 104, to provide smooth surfaces. The first major surface 104 may undergo various processing steps to divide the wafer 100 into the respective first semiconductor dies 102, and to form integrated circuits of the respective first semiconductor dies 102 on and/or in the first major surface 104. In embodiment shown, the dies 102 may each have four separate (independently accessible) memory planes, or channels CH0 to CH3. Each channel may also be comprised of more or lesser number of planes. Memory planes in each channel may be controlled independently. Separate, independently accessible memory planes increase the bandwidth for dies 102, but separate memory planes may be omitted in further embodiments. FIG. 2 further shows detail of a single semiconductor die 102 including a pattern of bonding or micro-bump pads 106 as explained below.

As shown in the cross-sectional edge view of FIG. 4, the processing of wafer 100 in step 200 may include the formation of integrated circuit memory cell array 122 formed in a semiconductor or dielectric substrate including layers 124. A reticle may be used to transfer an integrated circuit pattern for each semiconductor die 102 in a photolithography process. The patterned wafer can then undergo various processes such as etching, ion implantation, and deposition to create the actual semiconductor components and interconnections needed to build the integrated circuits of a semiconductor die 102. In embodiments, the integrated circuits may be a memory cell array 122 formed as a 3D stacked memory structure having strings of memory cells formed into layers. However, it is understood that the first semiconductor die 102 may be processed to include integrated circuits other than a 3D stacked memory structure. As noted above, in embodiments, the memory array 122 on each semiconductor die 102 may comprise for separate memory planes for each of the channels CH0 to CH3. A passivation layer 128, in one example, oxide layer or other dielectric layer, may be formed on top of the metal interconnect layers 130.

After formation of the memory cell array 122, internal electrical connections may be formed within the first semiconductor die 102 in step 204. The internal electrical connections may include multiple layers of metal interconnects 130, vias 132 and deep trench vias 134 formed sequentially through layers of the substrate 124. As explained below, deep trench vias 134 extend through the finished mDiP semiconductor device, where vias 132 may extend partially through the one or more dies of the mDiP semiconductor device. Each via 132, 134 may include a sidewall, a barrier metal and a filled metal as explained below. In embodiments, the filled metal may be copper, aluminum, alloys thereof or other conductive compounds as noted below.

As is known in the art, the metal interconnects 130, vias 132 and deep trench vias 134 may be formed for example by damascene processes a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 130 may be formed of a variety of electrically conductive metals including for example copper and copper alloys as is known in the art, and the vias 132 may be lined and/or filled with a variety of electrically conductive metals including for example tungsten, copper and copper alloys as is known in the art. As seen for example in FIG. 4, the metal interconnects 130, vias 132 and deep trench vias 134 may be formed to and through the memory cell array 122 to carry signals to and from the memory cell array 122 from the logic devices, and from the host devices.

In step 208, micro-bump pads 106 may be formed on the first (active) major planar surface 104 of the first semiconductor dies 102. As shown in FIGS. 2 and 4, these bump pads may be formed on top of vias 132 and/or 134 and may be used to transfer signals to and from the semiconductor die 102. The bump pads may be etched into the passivation layer 128, and each bump pad 106 may be formed over a liner 136. As is known in the art, the bump pads 106 may be formed for example of copper, aluminum and alloys thereof, and the liner 136 may be formed for example of a titanium/titanium nitride stack such as for example Ti/TiN/Ti, though these materials may vary in further embodiments. The bump pads 106 and liner 136 may be applied by vapor deposition and/or plating techniques. The integrated circuit memory arrays 122 may be electrically connected to the bump pads 106 by the metal interconnects 130 and vias 132, 134.

In step 210, the first (active) surface 104 of the wafer 100 may be supported on a temporary carrier (not shown) and the second (inactive) surface 105 may be thinned in a backgrind process to a final thickness of wafer 100 (shown in FIG. 4). The thinning of the wafer 100 may expose deep trench vias 134 at the second surface 105. Thereafter, in step 212, micro-bump pads 108 may be formed on the deep trench vias 134 on the inactive surface 105 as shown for example in FIG. 4.

FIG. 2 shows an example pattern of first semiconductor dies 102 on wafer 100. However, the patterns and number of first semiconductor dies 102 shown on wafer 100 in FIG. 2 is for illustrative purposes, and wafer 100 may include more or less first semiconductor dies 102 than are shown in further embodiments, and in different patterns. Similarly, the pattern and number of pads 106 and micro-bumps 108 on the first semiconductor die 102 shown in FIGS. 2 and 4 are shown for illustrative purposes. Each first die 102 may include more pads 106 and/or micro-bumps 108 than are shown in further embodiments, and may include various other patterns and densities of pads 106 and/or micro-bumps 108.

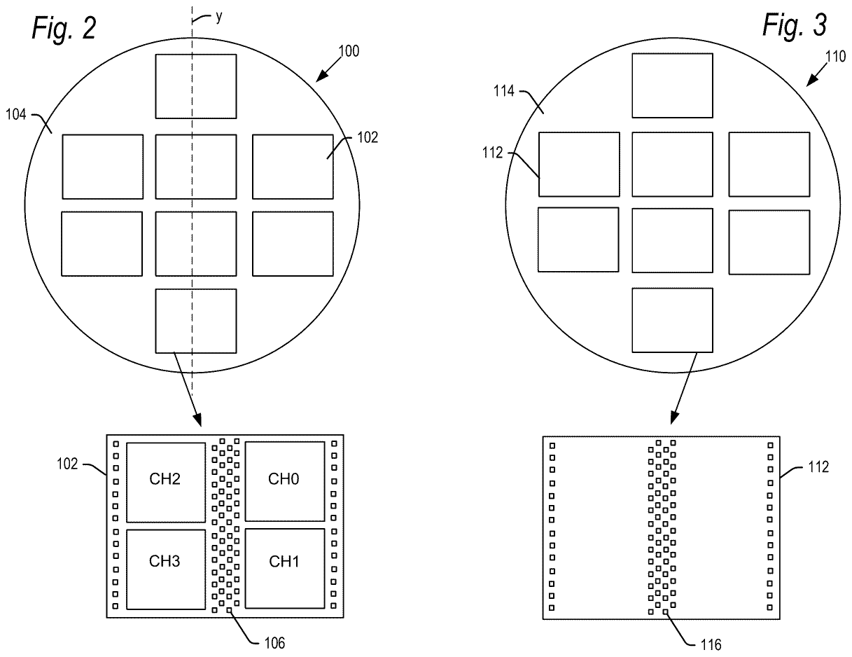

Before, after or in parallel with the formation of the first semiconductor dies on wafer 100, a second semiconductor wafer 110 may be processed into a number of second semiconductor dies 112, such as for example CMOS logic circuit dies, in step 220 as shown in FIG. 3. The semiconductor wafer 110 may start as an ingot of monocrystalline silicon grown according to either a CZ, FZ or other process. The second semiconductor wafer 110 may be cut and polished on both the first major surface 114, and second major surface 115 (FIG. 5) opposite surface 114, to provide smooth surfaces. The first major surface 114 may undergo various processing steps to divide the second wafer 110 into the respective second semiconductor dies 112, and to form integrated circuits of the respective second semiconductor dies 112 on and/or in the first major surface 114. FIG. 3 further shows detail of a single semiconductor die 112 including a pattern of micro-bump pads 116 as explained below.

In one embodiment, the second semiconductor dies 112 may be processed to include integrated circuits 142 formed in a semiconductor or dielectric substrate 144 as shown in the cross-sectional edge view of FIG. 5. Integrated circuits 142 may be configured as logic circuits to control read/write operations for one or more integrated memory cell arrays 122. The logic circuits may be fabricated using CMOS technology, though the logic circuits may be fabricated using other technologies in further embodiments. The second semiconductor dies 112 may include other and/or additional integrated circuits in further embodiments as explained below. A passivation layer, in one example oxide layer or other dielectric layer 148 may be formed on the upper surface 114.

After formation of the CMOS logic circuits 142, internal electrical connections may be formed within the second semiconductor die 112 in step 224. The internal electrical connections may include multiple layers of metal interconnects 150, vias 152 and deep trench vias 154 formed over the logic circuitry 142. The metal interconnects 150, vias 152 and deep trench vias 154 may be formed in the same manner as interconnects 130, vias 132 and deep trench vias 134 described above for dies 102.

As seen for example in FIG. 5, the metal interconnects 150 and vias 152 may be connected to the CMOS logic circuits 142 to carry signals to and from the logic circuits 142. In step 228, micro-bump pads 116 may be formed on the major planar surface 114 of the second semiconductor dies 112. As shown in FIGS. 3 and 5, these bump pads may be on top of vias 152. As is also explained below, the bump pads 116 are provided for transferring signals to and from the semiconductor die 112. The bump pads may be etched into the passivation layer 148, and may include liners 156. Bump pads 116 and liners 156 may be formed in the same manner as bump pads 106 and liners 136 described above. The CMOS logic circuits 142 may be electrically connected to the bump pads 116 by the metal interconnects 150 and vias 152, 154.

The number and patterns of second semiconductor dies 112 on wafer 110 in FIG. 3 is for illustrative purposes, and wafer 110 may include more or less second semiconductor dies 112, and other patterns of dies 112, in further embodiments. Similarly, the pattern of pads 116, as well as the number of bump pads 116, on the second semiconductor die 112 are shown for illustrative purposes. Each second die 112 may include more bump pads 116 than are shown in further embodiments, and may include various other patterns and densities of bump pads 116.

Once the fabrication of first and second semiconductor dies 102 and 112 is complete, the first and second semiconductor wafers 100 and 110 may be affixed to each other in step 230 so that the respective memory dies 102 are bonded to the CMOS logic circuit dies 112. The bonded wafers 100, 110 are referred to herein as CBA memory wafers 158, and each pair of bonded dies 102, 112 are referred to herein as a CBA memory die 160. An example of the completed CBA memory die 160 is shown for example in the cross-sectional edge view of FIG. 6.

To bond the dies 102, 112, the first semiconductor wafer 100 may be flipped over (relative to the view of FIG. 4), and bump pads 106 and 116 of the respective dies 102 and 112 may be physically and electrically coupled to each other. As shown and noted, the number and pattern of bump pads 106 may match the number and pattern of bump pads 116 so that the pads align with each other when the dies 102, 112 are coupled together. In embodiments where the number and pattern of bump pads 106, 116 are not symmetrical about a central vertical axis through the dies, the number and pattern of bump pads 106 may be the mirror image of the number and pattern of bump pads 116 so that the pads 106, 116 align when die 102 is flipped over.

The first and second semiconductor dies 102, 112 in the CBA memory die 160 may be bonded to each other by initially aligning the bump pads 106 and 116 on the respective dies 102, 112 with each other. Thereafter, the bump pads 106, 116 may be bonded together by any of a variety of bonding techniques, depending in part on bump pad size and bump pad spacing (i.e., bump pad pitch). These bonding techniques include for example Cu—Cu bonding, oxide-to-oxide bonding and hybrid bonding. The bump pad size and pitch may in turn be dictated by the number of electrical interconnections required for the CBA memory die.

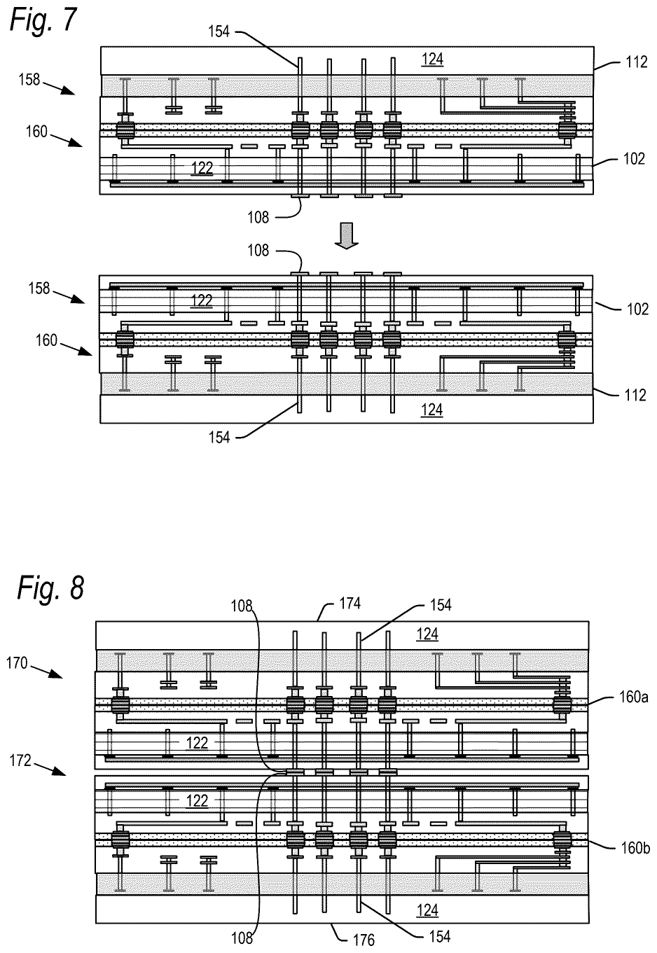

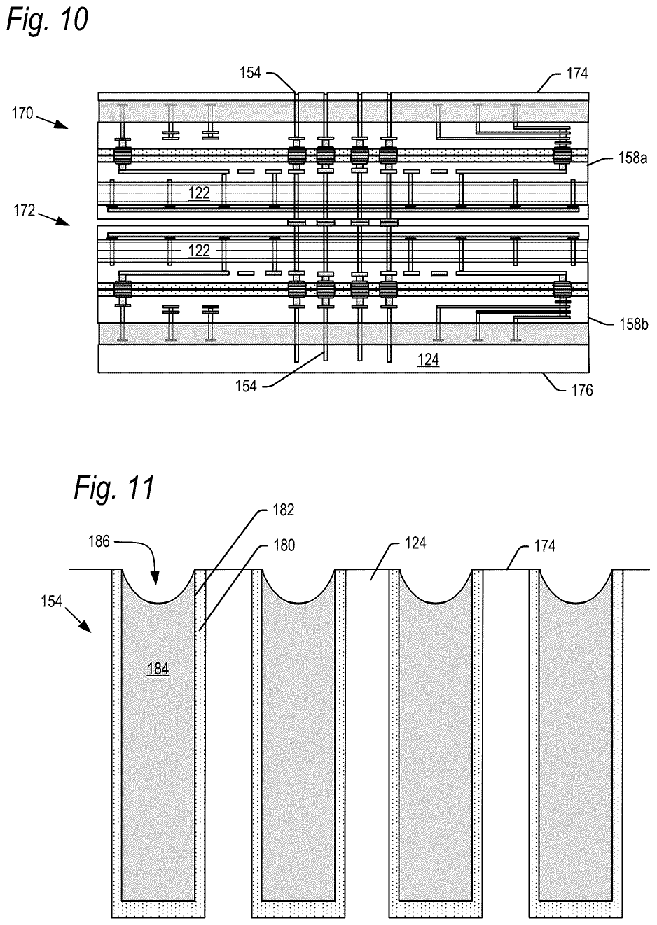

In step 226, two CBA memory wafers 158 may be bonded together face-to-face to form mirrored die pair (mDiP) wafers. As noted in the Background, bonding wafers face-to-face solves problems such as warping and chipping in packaging process or assembly. The active surfaces 104 of first and second CBA memory wafers 158 may be bonded to each other face-to-face as indicated in FIGS. 7 and 8. FIGS. 9 and 10 show further details of this bonding on the die level.

As shown in FIG. 7, one of the CBA memory wafer 158 may be flipped over and positioned on top of the second CBA memory wafer 158 so that the bump pads 108 on each of the respective CBA wafer 158 align with each other. The individual dies of CBA memory wafer 158 are referred to herein as dies 160. Once brought together, the bump pads 108 of the respective CBA memory wafers 158 may be physically bonded to each other as by Cu—Cu bonding, oxide-to-oxide bonding and hybrid bonding. Other wafer-to-wafer bonding techniques are possible. Such further techniques include various dielectric-to-dielectric bonding techniques including silicon-to-silicon bonding, and silicon-to-silicon dioxide bonding. The two joined CBA memory wafers 158a and 158b are referred to herein as the mirrored die pair (mDiP) wafers 170 as shown in FIG. 8. The individual dies, joined face-to-face in the mDiP wafers are referred to herein as mDiPs 172.

Further processing of the mDiP wafers 170 into completed mDiP semiconductor devices will now be explained with reference to the flowchart of FIG. 9. As shown in FIG. 8, the mDiP wafers 170 have a first major planar (inactive) surface 174 and an opposed second major planar (inactive) surface 176. One of the CBA memory wafers 158 (e.g., the top CBA wafer 158a) may undergo a backgrind process on the major planar surface 174 in step 230 to thin the wafer 110 of the first CBA memory wafer 158a, for example from 760 μm to a final thickness which may range from 10 μm to 36 μm. The surface 174 may then be polished in step 232. This structure is shown in FIG. 10. It is understood that the final thickness of the thinned wafer 110 may be larger or smaller than that range in further embodiments.

The backgrind and polishing processes of step 230 and 232 may expose the deep trench vias 154 to the major planar surface 174 of the top CBA memory wafer 158a. However, as noted in the Background section, the backgrind and polishing steps may also cause concave menisci to form in the vias 154 at the surface 174. This feature is shown in greater detail in FIG. 11. FIG. 11 shows the deep trench vias 154 formed in substrate 124. Each deep trench via 154 may include a sidewall 180, a barrier metal 182 and a filled metal 184 as noted above. The sidewall 180 may for example be formed of an oxide, such as silicon oxide. The barrier metal 182 may for example be Titanium Nitride and/or Titanium (TiN/Ti). And the filled metal 184 may for example be copper, aluminum and alloys thereof. The barrier metal 182 and filled metal 184 may be other low resistive metals, metal alloys, Si/metal alloys, or other binary or ternary compounds. FIG. 11 shows the concave meniscus 186 formed in each deep trench via 154 at the major planar surface 174.

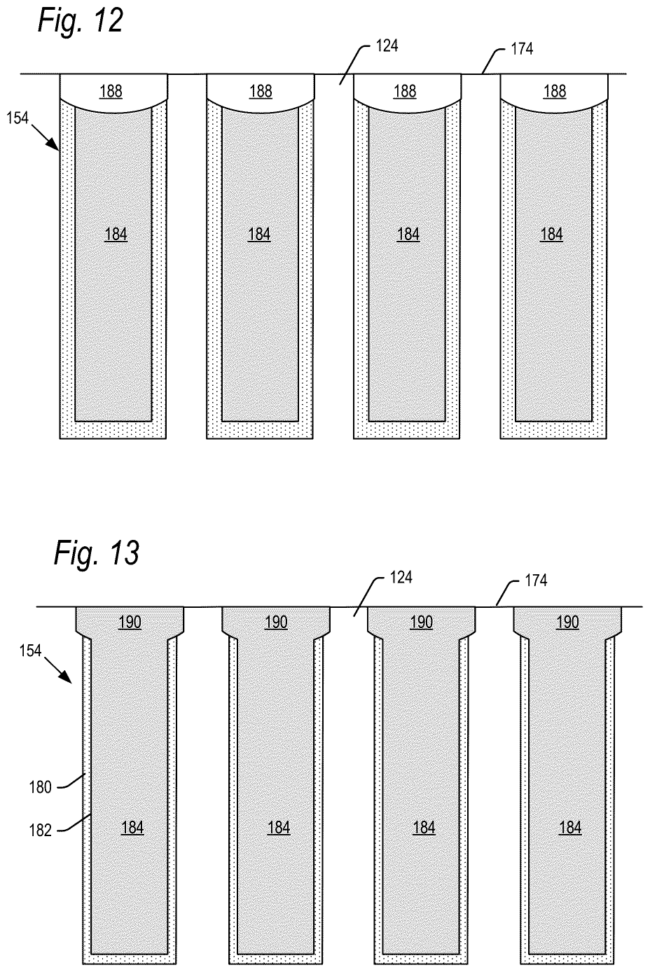

The concave menisci of the various deep trench vias 154 exposed at surface 174 are processed as will now be explained with respect to FIGS. 12 and 13. In step 234, the ends of the vias 154 at surface 174 are enlarged as shown at reference numbers 188 in FIG. 12. The enlarged portions 188 may remove the concave meniscus 186 at each deep trench via 154. The deep trench vias 154 (prior to step 234) may have a diameter of between 1 μm and 10 μm, though the diameter of the deep trench vias 154 may be larger or smaller than that in further embodiments. In step 234, the ends of vias 154 at surface 174 may be enlarged by 10% to 100%. In a further example, the ends of vias 154 at surface 174 may be enlarged by 25% to 75%. In a further example, the ends of vias 154 at surface 174 may be enlarged by 40% to 60%. These various ranges are by way of example only, and the ends of vias 154 at surface 174 may be enlarged by more or less than these ranges in further embodiments. The depth of the via enlargement from surface 174 may be 1 μm and 5 μm, though the depth of the via enlargement may be lesser or greater than this range in further embodiments.

The deep trench vias 154 may be enlarged at the surface 174 by various technologies, including for example chemical etching, plasma etching, laser ablation, ion and reactive ion etching, deep reactive ion etching and wet etching. It is understood that the via enlargement in step 234 may be enlarged by other methods in further embodiments. The shape of the enlargement may be circular, and concentric with the remainder of each deep trench via 154. The enlargement at each deep trench vias 154 may be other shapes in further embodiments.

In step 238, the enlarged portions 188 may be backfilled with a conductive, low resistance metal, including for example copper, aluminum and alloys thereof, to form enlarged micro-pads 190 as shown in FIG. 13. In embodiments, the backfill metal forming enlarged micro-pads 190 may be the same as the filled metal 184 forming the rest of the conductive portion of the deep trench vias 154.

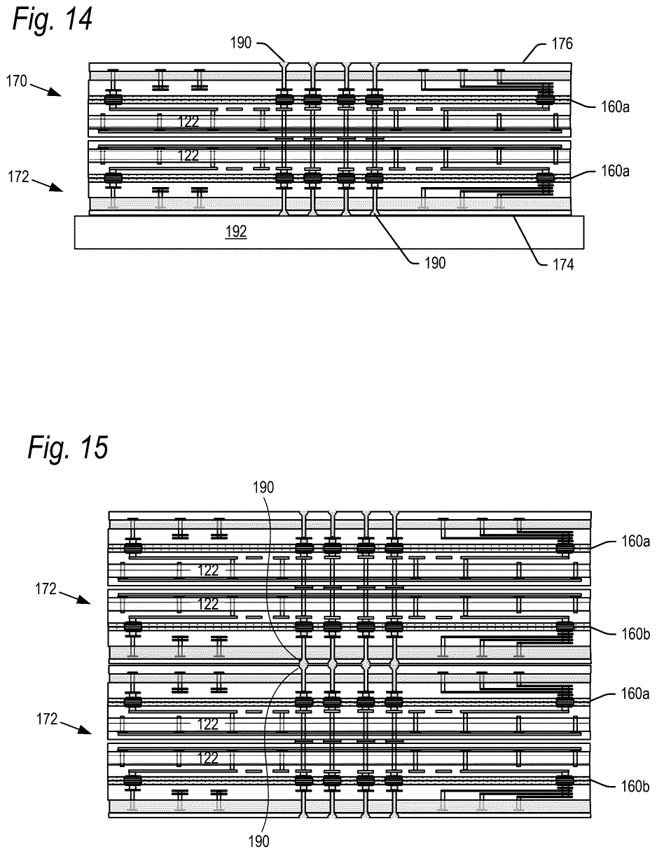

The mDiP wafers 170 may then be flipped over and the first major planar surface 174 may be supported on a temporary carrier 192 as shown in FIG. 14. Thereafter, the above steps may be repeated on the second major planar surface 176. In particular, the surface 176 may be thinned in backgrind and polishing steps 240, 242 to expose deep trench vias 154 and create concave menisci as described above. In step 244, enlarged portions 188 may be created at each deep trench via 154 at the second major planar surface 176, and the enlarged portions may be backfilled in step 248 to form enlarged micro-pads 190 on each deep trench via 154 at the second major planar surface 176 as shown in FIG. 14.

Although FIGS. 10 and 14 show individual mDiPs 172 for simplicity, at the stage of fabrication, the mDiPs 172 are still part of their respective mDiP wafers 170. After formation of the enlarged micro-pads 190 on the second major planar surface 176, the mDiP wafers 170 may be supported on a dicing tape, and the mDiP wafers 170 may be diced to form individual mDiPs 172 in step 250. Each of these mDiPs 172 includes first and second CBA memory dies 160a, 160b mounted to each other face-to-face. The mDiP memory wafers 170 may be diced into individual mDiPs 172 using for example stealth laser dicing. Saw blades and other traditional methods may be used in further embodiments. After dicing, the dicing tape may be spread apart to facilitate picking of the mDiPs 172 from the dicing tape by a pick and place robot (not shown).

In accordance with aspects of the present technology, given the face-to-face mounting of the respective CBA memory wafers 158a, 158b with the active surfaces of the respective wafers facing each other, the disparate coefficients of thermal expansion balance each other out, as does the strain otherwise resulting from materials having different thermal coefficients. As a result of this balance, warping of the mDiPs 172 is significantly or completely removed.

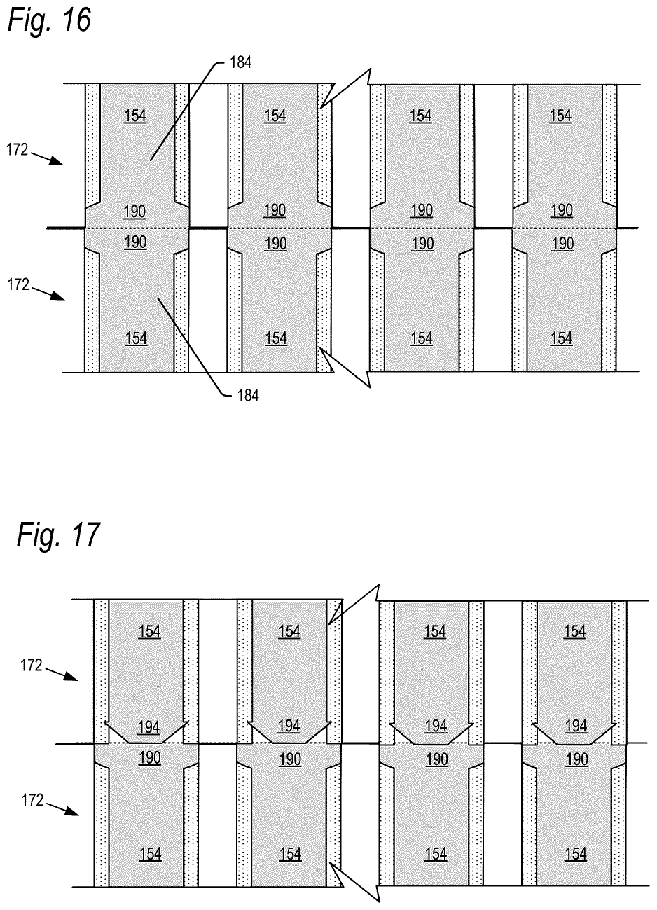

Moreover, the backfilled enlarged micro-bumps 190 ensure that respective mDiPs 172 may be stacked on top of each other and simply, securely and effectively physically and electrically bonded to each other. FIG. 15 shows a pair of mDiPs 172 electrically and physically bonded to each other by enlarged micro-bumps 190. FIG. 16 shows an enlarged partial view of the pair of mDiPss with the enlarged micro-bumps 190 of the deep trench vias 154 bonded to each other. The backfilled material ensures that the micro-bumps 190 of both mDiPs 172 are flush with their respective surfaces, thereby minimizing resistance and ensuring a secure bond. Moreover, the enlarged size ensures significant overlap even upon slight misalignment of the first and second sets of deep trench vias 154.

In embodiments, the enlarged micro-pads 190 may have a diameter greater than at least the filler metal 184. Such an embodiment is shown in FIG. 16. In further embodiments, the enlarged micro-pads 190 may have a diameter greater than the rest of the deep trench via as a whole (including sidewalls 180, barrier metal 182 and filler metal 184). Such an embodiment is shown in FIG. 13.

In embodiments described above, the tips of the deep trench vias 154 were processed by enlarging the via in step 234 and then backfilling the enlarged via in step 238. In further embodiments, the enlarging step 234 may be omitted. In this embodiment, the deep trench vias including the concave menisci 186 shown in FIG. 11 may simply be filled with the conductive metal in step 238 so that the surfaces of the deep trench vias 154 are flush with the surface 174.

FIG. 17 illustrates an alternative embodiment of the present technology. In this embodiment, one of the major (inactive) planar surfaces of an mDiP (for example surface 176) includes the enlarged micro-bumps 190 as described above. However, the opposed major (inactive) planar surface (174 in this example) includes deep trench vias 154 formed with a reduced-size micro-bumps 194. The reduced-size micro-bumps 194 may be formed in the same way as the enlarged micro-bumps 190. A portion of each of the deep trench vias 154 near the surface may be removed, as by chemical etching or the other techniques described above. Thereafter, a portion of space created by the removed material may be backfilled with a metal, for example the same metal as used for the filler metal 184. The backfilled metal may be shaped for example as a trapezoid with a decreasing diameter the closer the micro-bump is to the mDiP surface 174.

In this embodiment, the tip of the reduced-size micro-bumps 194 flush with the surface of the mDiP may have a smaller diameter than the filler material 184 to which the reduced-size micro-bumps 194 are joined. As shown in FIG. 17, the reduced diameter micro-bumps 194 will align entirely within the enlarged micro-bumps 190, even where there is some misalignment of the bonded mDiPs 172. Having complete overlap reduces contact resistance and improves the signal transfer between the joined mDiPs 172.

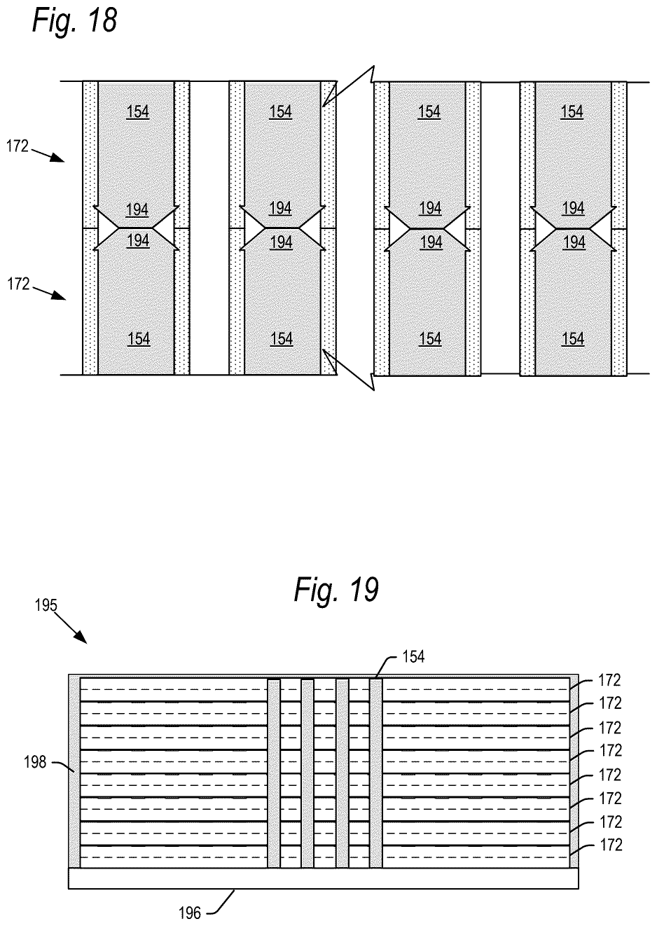

FIG. 18 shows a further embodiment of the present technology, where the deep trench vias 154 at both the first and second major planar surfaces 174, 176 are formed with reduced-size micro-bumps 194. Thus, when a pair of mDiPs are joined together, the reduced-size micro-bumps 194 on a first mDiP 172 electrically couple with the reduced-size micro-bumps 194 on the second mDiP 172.

FIG. 19 is a cross-sectional edge view of an mDiP semiconductor device 195 formed from a number of stacked and interconnected mDiPs 172. The deep trench vias 154 are shown extending through the entire mDiP semiconductor device 195. The deep trench vias 154 may connect to a controller die 196 mounted at a base of the device 195. The controller die 196 may for example be an ASIC, or a specialized processor such as an AI processor or a graphics processing unit. In general, the controller die controls the transfer of data to and from the memory cells of the mDiPs 172 in the stack. As noted, each mDiP 172 may be comprised of memory dies having multiple planes, thus allowing multiple reads/writes to occur to a single memory die of an mDiP 172 in parallel. This greatly increases the bandwidth of input/output operations to/from the mDiP semiconductor device 195. The controller die 196 may in turn be mounted to a host device (not shown) such as a printed circuit board.

The mDiP semiconductor device 195 may be encapsulated in a mold compound 198 which protects the mDiPs 172 in the stack. The encapsulation step may be performed by positioning an mDiP semiconductor device 195, or a panel of mDiP semiconductor devices 195 within a mold chase and injecting liquid mold compound over the mDiPs 172 and controller die 196. Other encapsulation processes may be used, including for example FFT (Flow Free Thin) compression molding, in further embodiments. Mold compound 198 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other encapsulants from other manufacturers are contemplated.

Referring back to FIGS. 4-6, in the embodiments described above, when forming the CBA memory die 160, the inactive surface 105 of memory dies 102 are thinned to expose deep trench vias 134. Thereafter, as described above, micro-bump pads 108 may be formed on the exposed deep trench vias 134. Next, an mDiP 170 may be formed by joining a pair of CBA memory dies 160 face to face as shown in FIG. 8 by physically and electrically coupling the micro-bump pads 108 of the respective CBA memory dies 160.

In accordance with a further aspect of the present technology, instead of forming micro-bump pads 108 on the exposed deep trench vias 134 (FIG. 4), enlarged micro-bumps 190 or reduced-size micro-bumps 194 may be formed on exposed deep trench vias 134. In this embodiment, the micro-bumps 190 and/or the reduced-size micro-bumps 194 may be formed on the exposed ends of deep trench vias 134 as described above with respect to FIGS. 12-13 and 16-18.

In embodiments described above, the backfilled vias 190, 194 are formed on exposed major planar surfaces of an mDiP. However, the backfilled vias 190, 194 of the present technology may be used on other types of finished semiconductor devices, including for example CBA semiconductor devices and other semiconductor memory devices. It is further understood that the backfilled micro-bumps may be formed on any vias of the present technology, whether the via is exposed after wafer thinning or otherwise.

In summary, one example of the present technology relates to a semiconductor device, comprising: a group of one or more semiconductor dies, the first group of one or more semiconductor dies comprising: a memory die, a first major planar surface, a second major planar surface, a first set of vias exposed at the first major planar surface, each via of the first set of vias comprising a conductive material and having a concave meniscus at the first major planar surface; and conductive backfill material backfilling the concave meniscus in said each via, the backfill material bringing each said via flush with the first major planar surface.

In another example, the present technology relates to a mirrored die pair (mDiP) semiconductor device, comprising: a first group of semiconductor dies, the first group of semiconductor dies comprising: a first memory die, a first CMOS logic circuit die bonded to the first memory die, a first major planar surface, a second major planar surface opposite the first major planar surface, a first set of vias exposed at the first major planar surface, each via of the first set of vias comprising a conductive material and having a concave meniscus at the first major planar surface; and conductive backfill material backfilling the concave meniscus in said each via of the first set of vias, the backfill material bringing each said via of the first set of vias flush with the first major planar surface; and a second group of semiconductor dies bonded to the first group of semiconductor dies, the second group of semiconductor dies comprising: a second memory die, a second CMOS logic circuit die bonded to the second memory die, a third major planar surface, and a fourth major planar surface opposite the third major planar surface.

In a further example, the present technology relates to a semiconductor device, comprising: a group of one or more semiconductor dies, the first group of one or more semiconductor dies comprising: a memory die, a first major planar surface, a second major planar surface, a first set of vias exposed at the first major planar surface, each via of the first set of vias comprising a conductive material and having a concave meniscus at the first major planar surface; and conductive backfill means for backfilling the concave meniscus in said each via and for bringing each said via flush with the first major planar surface.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A semiconductor device, comprising:
a group of one or more semiconductor dies, the first group of one or more semiconductor dies comprising:
a memory die,
a first major planar surface,
a second major planar surface,
a first set of vias exposed at the first major planar surface, each via of the first set of vias comprising a conductive material and having a concave meniscus at the first major planar surface; and
conductive backfill material backfilling the concave meniscus in said each via, the backfill material bringing each said via flush with the first major planar surface.

2. The semiconductor device of claim 1, wherein the portion of each of the vias comprising the conductive backfill material have enlarged diameters relative to the rest of each of said vias.

3. The semiconductor device of claim 1, wherein the portion of each of the vias comprising the conductive backfill material have a trapezoid shape narrowing toward the first major planar surface.

4. The semiconductor device of claim 1, wherein the portion of each of the vias comprising the conductive backfill material have diameters matching the rest of each of said vias.

5. The semiconductor device of claim 1, wherein the backfill material and the conductive material are the same.

6. The semiconductor device of claim 1, wherein the group of one or more semiconductor dies comprises a first group of one or more semiconductor dies, the memory die comprises a first memory die, the semiconductor device further comprising:
a third major planar surface,
a fourth major planar surface,
a second set of vias exposed at the fourth major planar surface, each via of the second set of vias comprising a conductive material and having a concave meniscus at the fourth major planar surface; and
conductive backfill material backfilling the concave meniscus in said each via of the second set of vias, the backfill material bringing each said via of the second set of vias flush with the fourth major planar surface.

7. The semiconductor device of claim 6, wherein the first and second groups of one or more semiconductor dies are physically and electrically coupled to each other at the second and third major planar surfaces.

8. The semiconductor device of claim 6, wherein the second and third major planar surfaces comprise bump pads, the bump pads of the second and third surfaces electrically and physically coupled to each other to bond the first and second groups of one or more semiconductor dies.

9. The semiconductor device of claim 8, wherein portions of the first set of vias comprising the conductive backfill material have enlarged diameters relative to the rest of the vias in the first set, and wherein portions of the second set of vias comprising the conductive backfill material have enlarged diameters relative to the rest of the vias in the second set.

10. The semiconductor device of claim 8, wherein portions of the first set of vias comprising the conductive backfill material have an enlarged diameter relative to the rest of the vias in the first set, and wherein portions of the second set of vias comprising the conductive backfill material have a trapezoid shape narrowing toward the fourth major planar surface.

11. The semiconductor device of claim 8, wherein portions of the first set of vias comprising the conductive backfill material have a trapezoid shape narrowing toward the first major planar surface, and wherein portions of the second set of vias comprising the conductive backfill material have a trapezoid shape narrowing toward the fourth major planar surface.

12. A mirrored die pair (mDiP) semiconductor device, comprising:
a first group of semiconductor dies, the first group of semiconductor dies comprising:
a first memory die,
a first CMOS logic circuit die bonded to the first memory die,
a first major planar surface,
a second major planar surface opposite the first major planar surface,
a first set of vias exposed at the first major planar surface, each via of the first set of vias comprising a conductive material and having a concave meniscus at the first major planar surface; and
conductive backfill material backfilling the concave meniscus in said each via of the first set of vias, the backfill material bringing each said via of the first set of vias flush with the first major planar surface; and
a second group of semiconductor dies bonded to the first group of semiconductor dies, the second group of semiconductor dies comprising:
a second memory die,
a second CMOS logic circuit die bonded to the second memory die,
a third major planar surface, and
a fourth major planar surface opposite the third major planar surface.

13. The mDiP semiconductor device of claim 12, wherein the portion of each of the vias in the first set of vias comprising the conductive backfill material have enlarged diameters relative to the rest of each of said vias in the first set of vias.

14. The mDiP semiconductor device of claim 12, wherein the portion of each of the vias in the first set of vias comprising the conductive backfill material have a trapezoid shape narrowing toward the first major planar surface.

15. The mDiP semiconductor device of claim 12, wherein the portion of each of the vias in the first set of vias comprising the conductive backfill material have diameters matching diameters of the conductive material in each of said vias in the first set of vias.

16. The mDiP semiconductor device of claim 12, wherein the backfill material and the conductive material are the same.

17. The mDiP semiconductor device of claim 12, the second set of semiconductor dies further comprising:
a second set of vias exposed at the fourth major planar surface, each via of the second set of vias comprising a conductive material and having a concave meniscus at the fourth major planar surface, and
conductive backfill material backfilling the concave meniscus in said each via of the second set of vias, the backfill material bringing each said via of the second set of vias flush with the fourth major planar surface.

18. The mDiP semiconductor device of claim 17, wherein the first and second groups of semiconductor dies are physically and electrically coupled to each other at the second and third surfaces, face to face.

19. The mDiP semiconductor device of claim 10, wherein portions of the first and second sets of vias comprising the conductive backfill material both have enlarged diameters relative to the rest of the first and second sets of vias, the enlarged diameter vias enhancing an electrical connection between said mDiP semiconductor devices in a stack of said mDiP semiconductor devices.

20. A semiconductor device, comprising:
a group of one or more semiconductor dies, the first group of one or more semiconductor dies comprising:
a memory die,
a first major planar surface,
a second major planar surface,
a first set of vias exposed at the first major planar surface, each via of the first set of vias comprising a conductive material and having a concave meniscus at the first major planar surface; and
conductive backfill means for backfilling the concave meniscus in said each via and for bringing each said via flush with the first major planar surface.
